(19) United States
(12) Patent Application Publication
(10) Pub. No.: US 2025/0233405 A1
(43) Pub. Date: Jul. 17, 2025

(54) LEAKAGE PROTECTION DEVICE WITH LOAD-END FUNCTIONS

(71) Applicant: Chengli LI, Suzhou (CN)

(72) Inventors: Chengli LI, Suzhou (CN); Jinxin ZHANG, Suzhou (CN); Xiaoming ZHANG, Suzhou (CN); Long CHEN, Suzhou (CN)

(73) Assignee: Chengli LI, Suzhou (CN)

(21) Appl. No.: 19/098,807

(22) Filed: Apr. 2, 2025

Related U.S. Application Data
(63) Continuation-in-part of application No. 18/350,817, filed on Jul. 12, 2023.

(30) Foreign Application Priority Data
Jun. 16, 2023 (CN) 202310715960.5
Jun. 16, 2023 (CN) 202321540120.1
Mar. 28, 2025 (CN) 202520561875.2

(51) Int. Cl. H02H 3/08; H01R 13/713; H05K 7/20

(52) U.S. Cl. CPC H02H 3/08; H01R 13/713; H05K 7/2039

(57) ABSTRACT

A leakage protection device with additional functions. The device includes a housing, an input terminal for coupling to a power supply, an output terminal for coupling to an electrical load, and a core assembly disposed in the housing. The core assembly includes a leakage protection assembly, including at least a leakage protection circuit board for detecting a leakage current signal at the output terminal; an additional function assembly, coupled to the leakage protection assembly and including at least an additional function circuit board for performing at least one load end function. The leakage protection circuit board and the additional function circuit board are stacked in parallel with each other, and the leakage protection circuit board is locater farther away from the input terminal than the additional function circuit board is. The device integrates the additional function assembly in the leakage protection device and optimizes the structural layout.

### BACKGROUND OF THE INVENTION

The present invention generally relates to the field of leakage protection devices, and more particularly to a leakage protection device with additional (e.g., load-end) functions.

With the improvement of living standards and people's awareness of electricity safety, the application scenarios of devices with leakage protection function are becoming more and more extensive. Traditional leakage protection devices only provide leakage protection functions, but with the changes in market demand, the types of electrical equipment or loads that are equipped with leakage protection devices are also increasing. With the increasing reliability and functional requirements of leakage protection devices, the new functions of certain loads have put forward additional functional requirements for leakage protection devices. Therefore, there is a need for a device that can add some functions of load-side electrical equipment to leakage protection devices.

### SUMMARY OF THE INVENTION

Accordingly, embodiments of the present invention provide a leakage protection device with additional functions, which meets the demand for additional functions at the load end with an efficient structural layout and a compact design.

In one aspect, the present invention provides a leakage protection device with additional functions, which includes: a housing, an input terminal for coupling to a power supply, an output terminal for coupling to an electrical load, and a core assembly disposed in the housing, the core assembly including: a leakage protection assembly, including at least a leakage protection circuit board, configured to detect a leakage current signal at the output terminal; an additional function assembly, coupled to the leakage protection assembly, and including at least an additional function circuit board, configured to perform at least one load-end function, wherein the leakage protection circuit board and the additional function circuit board are stacked in parallel with each other, and the leakage protection circuit board is located farther away from the input terminal than the additional function circuit board is.

Based on the above technical characteristics, the present invention may include any one or more of the embodiments below.

In some embodiments, the leakage protection assembly includes at least a detection assembly and a disconnection assembly. The detection assembly detects a leakage current signal at the output end, and the disconnection assembly disconnects the power supply in response to the leakage current signal.

In some embodiments, the detection assembly includes a detection magnetic ring, which has an inner hole and is coupled to the leakage protection circuit board, configured to detect the leakage current signal of the power supply path passing through the inner hole and to transmit the signal to the leakage protection circuit board.

In some embodiments, the disconnection assembly includes an input stationary contact assembly coupled to the input terminal and an output moving contact assembly passing through the inner hole of the detection magnetic ring and coupled to the output terminal, wherein the disconnection assembly is configured to disconnect the electrical connection between the input stationary contact assembly and the output moving contact assembly in response to the leakage current signal.

In some embodiments, the leakage protection assembly includes an operating assembly mechanically linked with the disconnection assembly, wherein the operating assembly includes a reset assembly and a trip assembly configured to switch the input stationary contact assembly and the output moving contact assembly between a connected state and a disconnected state.

In some embodiments, the operating assembly further includes a test assembly, coupled to the leakage protection circuit board and configured to generate a simulated leakage signal.

In some embodiments, the leakage protection device further includes a heat sink, disposed near components on the leakage protection circuit board and/or the additional function circuit board that are heat-generating, configured to dissipate heat for the heat-generating components.

In some embodiments, the leakage protection device further includes a heat conductor disposed on the heat sink at a position corresponding to the heat-generating components, wherein the heat conductor is in contact with the heat-generating components and the heat sink respectively, and configured to transfer heat between the heat-generating components and the heat sink.

In some embodiments, the leakage protection device further includes an insulating member, disposed between the heat sink and the leakage protection circuit board and/or the additional function circuit board.

In some embodiments, the leakage protection device further includes a status indicator formed of a light-transmitting material and disposed between the leakage protection circuit board and the housing.

In some embodiments, the input terminal includes at least two prongs extending out of the housing, and the leakage protection circuit board and the additional function circuit board are disposed perpendicular to a plugging direction of the prongs, wherein the prongs are electrically coupled to the leakage protection circuit board or the additional function circuit board via prong wires.

In some embodiments, the housing includes at least an upper cover and a bottom cover, wherein the upper cover includes an output terminal through hole configured to accommodate a power cord, and the bottom cover includes input terminal through holes configured for the prongs to pass through.

In some embodiments, the housing further includes a middle cover disposed between the upper cover and the bottom cover, configured to fix the prongs.

In some embodiments, the middle cover has screw holes configured to accommodate screws for fixing the middle cover to the upper cover or the bottom cover.

In some embodiments, the bottom cover completely encloses the middle cover in the housing.

In some embodiments, the leakage protection device further includes a wire crimping assembly, configured to fix the power cord in the housing, and is moveable only in a plugging direction of the prongs.

In some embodiments, the leakage protection device further includes a power cord bending buffer device, which has a snap-fitting convex edge, wherein the snap-fitting convex edge passes through the output through hole of the housing and is matched and fixed with the wire crimping assembly.

In some embodiments, the wire crimping assembly includes a first crimping block and a second crimping block disposed opposite to each other along the plugging direction of the prongs, wherein the first crimping block has a first notch, the second crimping block has with a second notch, wherein the first notch and/or the second notch has an inclined surface, wherein the inclined surface is engaged with the snap-fitting convex edge of the power cord bending buffer device.

In some embodiments, the leakage protection device further includes a support frame disposed between the leakage protection assembly and the additional function assembly, wherein the leakage protection circuit board and the additional function circuit board are electrically connected with each other via conductive columns passing through the support frame.

In some embodiments, the support frame has a wire management block configured to bend the power cord.

In some embodiments, the load-end function includes at least a power conversion function and/or an electromagnetic compatibility filtering function and/or a switch control function.

Embodiments of the present invention integrate additional functional components in the leakage protection device and optimize the structural layout, so that while providing leakage protection function, at least part of the functions of the load-end electrical equipment can be performed in a limited space, thereby ensuring the reliability of the leakage protection device while having more diversified functions. The device is suitable for a variety of electrical equipment, and provides users with a richer leakage protection device integration solution. In addition, the leakage protection device described herein has a simple structure and is easy to implement and applicable to a wide range of application scenarios.

### BRIEF DESCRIPTION OF DRAWINGS

Other features and advantages of the present invention may be understood from the embodiments described below with reference to the drawings.

FIG. 1 is an exterior view of a leakage protection device according to an embodiment of the present invention.

FIG. 2 is an exploded view of the leakage protection device of FIG. 1.

FIG. 3A illustrates the assembled core assembly that includes a leakage protection assembly and an additional function assembly in the leakage protection device of FIG. 2.

FIG. 3B is an exploded view of the core assembly of FIG. 3A.

FIG. 4 is an exploded view of the core assembly of FIG. 3A and the housing and the button assembly.

FIG. 5A illustrates the leakage protection assembly according to an embodiment of the present invention.

FIG. 5B is an exploded view of the leakage protection assembly of FIG. 5A.

FIG. 6A is a cross-sectional view showing the positions of various components of the leakage protection assembly when the assembly is in a disconnected state.

FIG. 6B is a cross-sectional view showing the positions of various components of the leakage protection assembly when the reset button is operated (pressed) in the state shown in FIG. 6A.

FIG. 6C is a cross-sectional view showing the positions of various components of the leakage protection assembly when the reset button is operated (released) in the state shown in FIG. 6B to put the leakage protection assembly in a closed state.

FIG. 7 is an exploded view of the core assembly, the upper cover of the housing, the output power cord assembly, and the wire crimping assembly.

FIG. 8A is a cross-sectional view of the leakage protection device in an assembled state in which the wire crimping assembly clamps and fixes the output power cord assembly to the through hole of the output side of the housing.

FIG. 8B illustrates the assembled leakage protection device where the power cord is bent into a U shape inside the housing by the wire management block and the wire baffle.

FIG. 9 is a circuit diagram of a leakage protection device according to an embodiment of the present invention.

### DETAILED DESCRIPTION OF THE INVENTION

The implementation and use of the embodiments are discussed in detail below. However, it should be understood that the specific embodiments discussed are merely exemplary of specific ways to implement and use the present invention, and are not intended to limit the scope of the present invention. When describing the structural positions of the various components, such as up, down, top, bottom, etc., the expressions of directions are not absolute, but relative. When the various components are arranged as shown in the figure, these directional expressions are appropriate, but when the positions of the various components in the figure change, these directional expressions also change accordingly.

In the descriptions below, terms such as “comprising”, “including”, “containing”, “having”, etc. are intended to be open-ended and do not exclude elements or components not specifically listed.

In this disclosure, unless otherwise indicated, terms such as “mount”, “connect”, “couple”, “link” etc. should be understood broadly; for example, they may be fixed connections, or removable or detachable connections, or integrally connected for integrally formed; they may be directly connected, or indirectly connected via intermediate parts, and may refer to internal connection of two components or mutual interactions of two components. Those skilled in the relevant art can readily understand the meaning of these terms as used in this disclosure based on the specific description and context.

In this disclosure, unless specifically indicated, terms such as “first”, “second”, etc. do not connote a temporal or spatial sequence or a particular number of parts.

Traditional leakage protection plugs only have leakage power shut off protection functions, and are relatively simple and have limited application scenarios. In order to meet more diversified application needs, for example, when the device is adapted to high-speed hair dryers, curling irons and other scenarios, it is necessary to solve high-frequency electromagnetic interference or provide DC power supply, and in order to make the load end light and compact, it is desirable to provide an electromagnetic compatibility module or a DC power supply module in the leakage protection plug, so as to provide users with a safe and comfortable experience.

Accordingly, the present invention provides a leakage protection device with additional functions, which realizes certain functions of electrical equipment and has an efficient structural layout and a compact design, in response to the trend that existing leakage protection devices need to be adapted to different electrical equipment and have increasing functional requirements.

The leakage protection device in the form of a plug is described below as an example, but it should be understood that the leakage protection device may be applicable to other forms such as a power outlet socket.

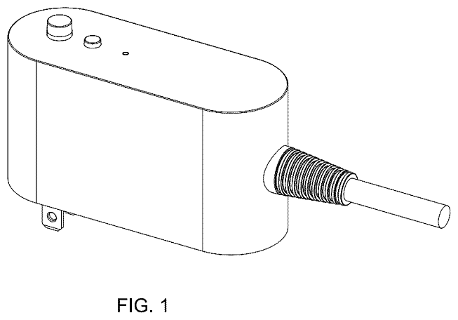

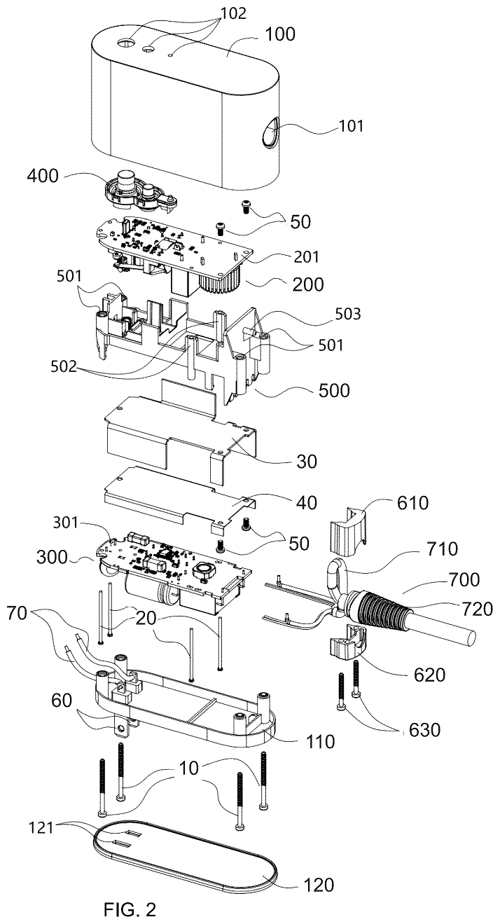

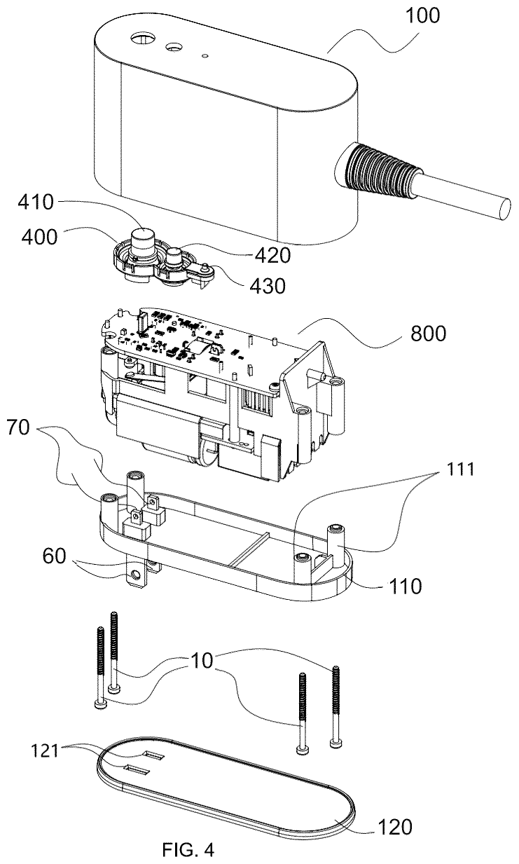

Referring to FIG. 1 and FIG. 2, a leakage protection device according to an embodiment of the present invention includes a housing and a core assembly disposed in the housing, and an output power cord assembly connected to the housing and extending out of the housing. The housing may include, for example, an upper cover 100 and a bottom cover 120, and a middle cover 110 may also be disposed between the upper cover 100 and the bottom cover 120 to support or fix the components in the housing, as will be described below. In some embodiments, the middle cover 110 is provided with a screw hole 111 (FIG. 4) for accommodating screws that fix the middle cover 110 relative to the upper cover 100 or the bottom cover 120, so that they can be fixedly connected to each other by fasteners such as screws 10. In the illustrated embodiment, the bottom cover 120 is fixed to the upper cover 100 or the middle cover 110 by a snap-on method, for example. And, advantageously, the bottom cover 120 completely encloses the middle cover 110 in the housing.

In the illustrated embodiment, the leakage protection device includes an input terminal for coupling with a power source and an output terminal for coupling with a load terminal, wherein the input terminal includes at least two prongs 60 extending out of the housing for inserting into a socket to obtain power, and the prongs 60 can be fixed on the middle cover 110, and the bottom cover 120 is provided with input terminal through holes 121 for the prongs 60 to extend out. The side of the upper cover 100 is also provided with an output terminal through hole 101 for accommodating a power cord, that is, an output power cord assembly 700, for achieving electrical connection with the electrical load. The core assembly includes a leakage protection assembly 200 and an additional function assembly 300. The leakage protection assembly 200 includes at least a leakage protection circuit board 201 to detect a leakage current signal at the output side. The additional function assembly 300 is coupled to the leakage protection assembly 200 and includes at least one additional function circuit board 301 and a functional component coupled to the additional function circuit board 301 to achieve at least one load-side function.

According to the present embodiment, the load-side function at least includes a power conversion function (AC/DC or DC/DC conversion) and/or an electromagnetic compatibility (EMC) filtering function and/or a switch control function. The additional function assembly 300 can combine two or three of, or select any one of, the power conversion function, the electromagnetic compatibility filtering function, and the switch control function. It should be understood that the functional components may be various electronic devices for realizing, for example, AC/DC or DC/DC conversion functions and/or EMC filtering functions and/or switch control functions, including but not limited to capacitors, inductors, resistors, etc.

Advantageously, as shown in FIG. 2, the leakage protection circuit board 201 and the additional function circuit board 301 are stacked in parallel with each other, and the leakage protection circuit board 201 is farther away than the additional function circuit board 301 from the input terminal, that is, the leakage protection circuit board 201 is disposed farther away from the prongs 60. In addition, the leakage protection circuit board 201 and the additional function circuit board 301 are arranged perpendicular to the plugging direction of the prongs 60. The prongs 60 are coupled to the additional function circuit board 301 or the leakage protection circuit board 201 via the prong wires 70.

Using this structure, the leakage protection device of the present embodiment integrates additional functional assembly in a limited housing space with an optimized structural layout, ensuring the reliability of the leakage protection device while having more diversified functions. In addition, by placing the leakage protection circuit board 201 farther away than the additional function circuit board 301 from the input terminal, the leakage protection circuit which involves low-voltage signal processing can be physically isolated from the high-voltage circuit at the input side, avoiding the direct impact of high-voltage arc or breakdown risk on the low-voltage circuit, improving overall safety. In addition, the leakage protection function relies on the zero-sequence current transformer to detect small differences (usually milliampere level) between the currents on the hot wire and the neutral wire. If the leakage protection circuit board is close to the input terminal, it is susceptible to interference from large current, power supply noise and high-frequency harmonics, resulting in misjudgment or decreased sensitivity. The layout that places it farther away from the input terminal can reduce the impact of electromagnetic interference on the signal amplification circuit, ensure the accuracy of leakage detection, and also help prevent false triggering or failure caused by voltage fluctuations, thereby ensuring the reliability and response speed of the leakage protection function under complex working conditions.

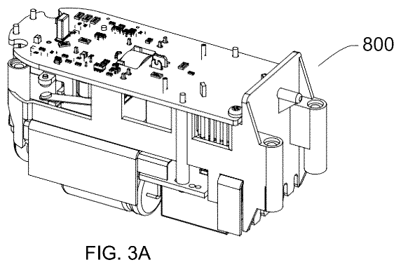

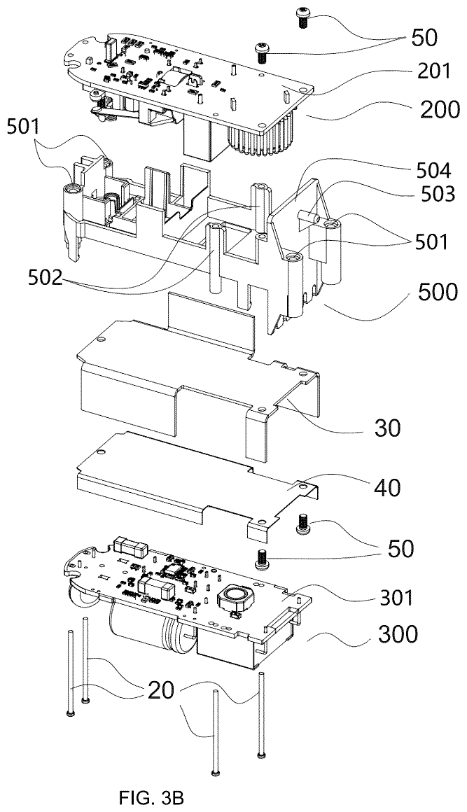

FIG. 3A and FIG. 3B respectively show assembled and exploded views of a core assembly 800 which includes a leakage protection assembly 200 and an additional function assembly 300. FIG. 4 is an exploded view of the core assembly 800 with a housing and a button assembly 400. In the illustrated embodiment, the leakage protection device further includes a support frame 500, which is disposed between the leakage protection assembly 200 and the additional function assembly 300. The electronic components of the leakage protection assembly 200 and the additional function assembly 300 can be accommodated in the support frame or positioned and supported by the support frame. The leakage protection circuit board 201 and the additional functional circuit board 301 are electrically connected via the conductive column 20 passing through the support frame 500. For example, a conductive column through hole 502 may be provided in the support frame 500, and the conductive column 20 passes through the conductive column through hole 502, and the two ends are respectively connected to the leakage protection circuit board 201 and the additional functional circuit board 301 to achieve electrical connection between the two circuit boards. As shown in FIGS. 3B and 4, the middle cover 110 is provided with screw holes 111 at the edge, and the screws 10 can pass through the screw holes 111 and the screw columns 501 of the support frame 500 and be assembled and fixed with the screw holes (not shown) of the upper cover.

In some embodiments, the leakage protection device further includes a heat sink 30, which is disposed near components on the leakage protection circuit board 201 and/or the additional function circuit board 301 that are heat generating, and is used to dissipate heat for these heat-generating components. In the illustrated embodiment, the heat sink 30 is, for example, disposed near the additional function circuit board 301, and can be constructed as a substantially plate-shaped member with heat dissipation portions that are bent and extended from the plate-shaped portion in opposite directions, respectively, to dissipate heat for the heat-generating components on the leakage protection circuit board 201 and the additional function circuit board 301, as shown in FIG. 3B. In some embodiments, a heat conductor may be provided at a position corresponding to the heat-generating components on the heat sink 30, and the heat conductor is in contact with the heat-generating components and the heat sink, respectively, to transfer heat between the heat-generating components and the heat sink. According to different needs, the heat conductor may be selected from, for example, mica sheets, ceramic thermal conductors, metal thermal conductors combined with insulating layers, thermally conductive silicone, and the like.

In some embodiments, the leakage protection device further includes an insulating member 40, which is disposed between the heat sink 30 and the leakage protection circuit board 201 and/or the additional function circuit board 301, so as to ensure the insulation effectiveness between the heat sink and the leakage protection circuit board and/or the additional function circuit board. In the illustrated embodiment, the insulating member 40 is disposed between the additional function circuit board 301 and the heat sink 30, and can be fixed to the support frame 500 together with the heat sink 30 by fixing screws 50.

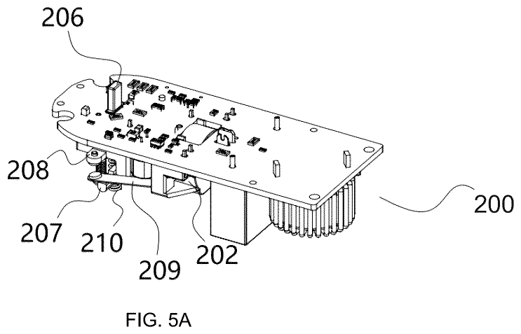

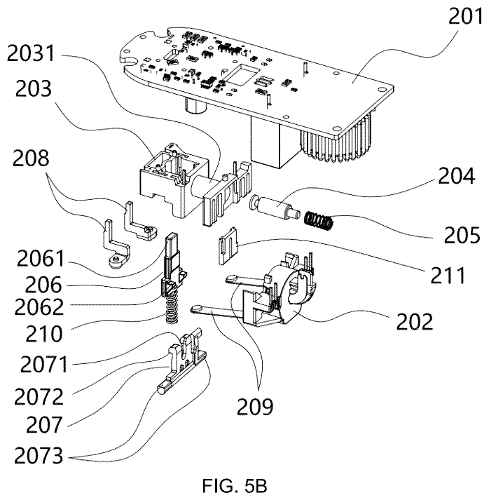

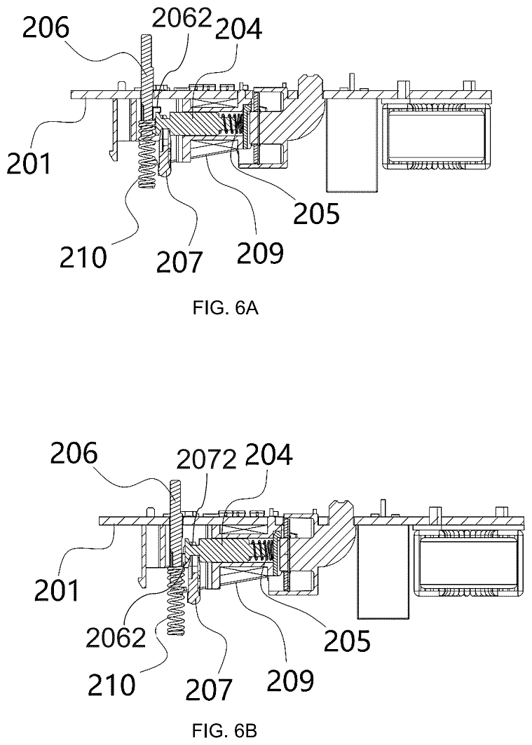

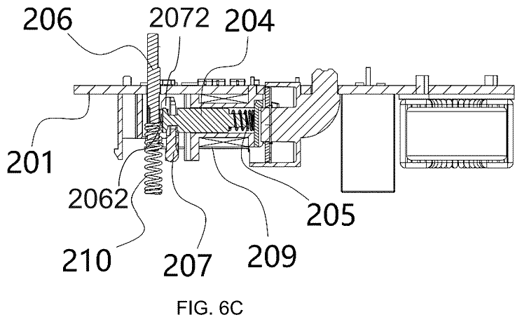

Specifically, for the leakage protection assembly 200, referring to FIG. 5A to FIG. 6C, in some embodiments, the leakage protection assembly 200 includes at least a detection assembly 202 and a disconnection assembly. The detection assembly 202 detects a leakage current signal at the output side, and the disconnection assembly disconnects the power supply circuit in response to the leakage current signal. It should be understood that the disconnection assembly may have any structure capable of disconnecting the power supply path between the input terminal and the output terminal, and may also be referred to as a switch assembly, for example, including but not limited to a contact arm that realizes on-off switch through a contact.

In the illustrated embodiment, the detection assembly 202 may include a detection magnetic ring, which is provided with an inner through hole and coupled to the leakage protection circuit board 201, for detecting the leakage current signal of the power lines passing through the inner through hole and transmitting the signal to the leakage protection circuit board 201. The disconnection assembly may include an input stationary contact assembly 208 coupled to the input terminal and an output movable contact assembly 209 passing through the inner through hole of the detection magnetic ring and coupled to the output terminal. The input stationary contact assembly 208 has stationary contact terminals and is coupled to the prongs 60 by the prong wires 70, and the output movable contact assembly 209 has movable contact terminals and is coupled to the output power cord assembly 700 after passing through the inner through hole of the detection assembly 202. The disconnection assembly disconnects the electrical connection between the input stationary contact assembly 208 and the output movable contact assembly 209 in response to the leakage current signal. The leakage protection assembly 200 further includes an operating assembly mechanically linked to the disconnection assembly. The operating assembly includes a reset assembly 206 and a tripping assembly 207 to switch the input stationary contact assembly 208 and the output moving contact assembly 209 between a connected (closed) state and an disconnected (open) state, that is, the output moving contact assembly 209 can be driven by the operating assembly to close and connect with the input stationary contact assembly 208, or to separate and disconnect from the input stationary contact assembly 208 due to its own clastic deformation rebound force.

Referring to FIG. 5B, the reset assembly 206 is formed in the form of a reset rod, one end of which is a reset plate head end 2061, which can be matched with the reset button 410 (FIG. 4) protruding from the upper cover 100. The other end of the reset rod abuts against one end of the reset spring 210, and the other end of the reset spring 210 abuts against the support frame 500, which is used to provide an upward rebound force to the reset rod 206. In some embodiments, the operating assembly also includes a test assembly, which is coupled to the leakage protection circuit board 201, and configured to generate a simulated leakage signal. As shown in FIG. 4, the test assembly includes a test button 420. In some embodiments, the leakage protection device may also include a status indicator 430, which is formed of a light-transmitting material and disposed between the leakage protection circuit board 201 and the housing. According to different needs, the reset button 410 and the test button 420 may be formed as one body and may be combined with the status indicator 430, to form a button assembly 400.

Correspondingly, the upper cover 100 is provided with a guide hole 102 (FIG. 2) for the reset button 410 and the test button 420 to protrude, so as to facilitate the operation of the reset member and the test member. In the case where a status indicator 430 is provided, the guide hole 102 also exposes the status indicator 430 so as to allow visual observation of the working status of the leakage protection device from the outside of the housing.

Referring back to FIG. 5B, in the illustrated embodiment, the tripping assembly 207 cooperates with the tripping coil assembly 203. The tripping coil assembly 203 includes a hollow winding column 2031, the outer side of which is wound with a coil winding coupled to the leakage protection circuit board 201, and a tripping iron core 204 is placed in the inner hole of the hollow winding column 2031. The head end of the tripping iron core 204 is clamped with the tripping assembly 207, the tail end of the tripping iron core 204 is abutted against one end of the iron core spring 205. The other end of the iron core spring 205 is abutted against the side of the spring baffle 211, and the spring baffle 211 is plugged into and fixed to the end of the inner through hole of the hollow winding column 2031. The tripping assembly 207 has a tripping notch 2071, a tripping buckle 2072, and a tripping lifting arm 2073. The tripping notch 2071 is engaged with the head end of the tripping iron core 204 and can move with the movement of the tripping iron core 204. The reset assembly 206 is correspondingly provided with a reset buckle 2062 on the side of the reset rod to engage with or separate from the tripping buckle 2072. The tripping lifting arm 2073 is configured to contact the output moving contact assembly 209 to switch the input stationary contact assembly 208 and the output moving contact assembly 209 between the closed state and the open state. It should be understood that the structures of the reset assembly and the tripping assembly shown in the figures are only examples, and depending on different needs, the above structures may be changed accordingly to attain similar reset and tripping functions.

Referring to FIGS. 6A to 6C, in the initial state, as shown in FIG. 6A, the iron core spring 205 is in a compressed state and applies a rebound force to the tripping iron core 204. Accordingly, the tripping iron core 204 is subjected to the elastic force of the iron core spring 205, so that the tripping buckle 2072 applies a maintaining force to the tripping assembly 207 in the direction of the reset assembly 206, so as to have a tendency to engage with the reset buckle 2062 of the reset assembly 206. When the reset button 410 is depressed, the linked reset assembly 206 moves downward and compresses the reset spring 210 until the tripping buckle 2072 of the tripping assembly 207 engages with the reset buckle 2062 of the reset assembly 206, as shown in FIG. 6B. At this time, if the reset button 410 is released, and the reset assembly 206 will drive the tripping assembly 207 and the output moving contact assembly 209 to move upward under the action of the rebound force of the reset spring 210, forcing the output moving contact assembly 209 to undergo elastic deformation until the output moving contact assembly 209 is connected and closed with the input stationary contact assembly 208, as shown in FIG. 6C.

When the detection assembly 202 detects a leakage current signal, the tripping coil assembly 203 responds to the control of the leakage protection circuit board 201 and is powered on to generate a magnetic field to drive the tripping iron core 204 to compress the iron core spring 205 and pull the tripping assembly 207, so that the tripping buckle 2072 of the tripping assembly 207 is separated and disconnected from the reset buckle 2062 of the reset assembly 206. At this time, the tripping lifting arm 2073 of the tripping assembly 207 moves downward to its initial position under the action of the deformation rebound force of the output moving contact assembly 209, and the output moving contact assembly 209 is separated and disconnected from the input stationary contact assembly 208, as shown in FIG. 6A, thereby achieving leakage protection.

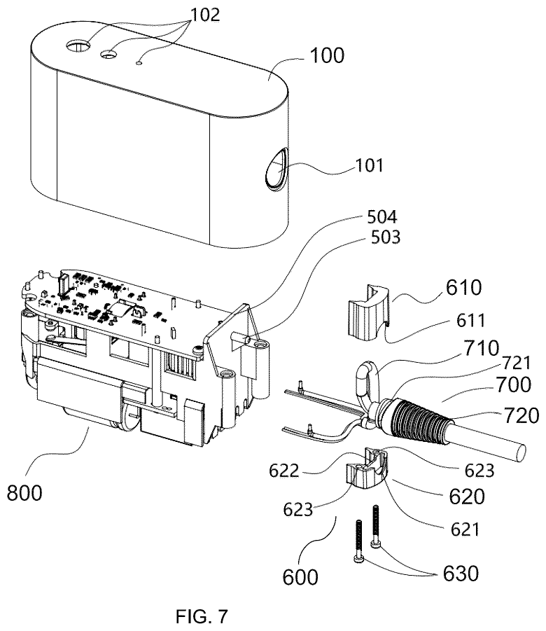

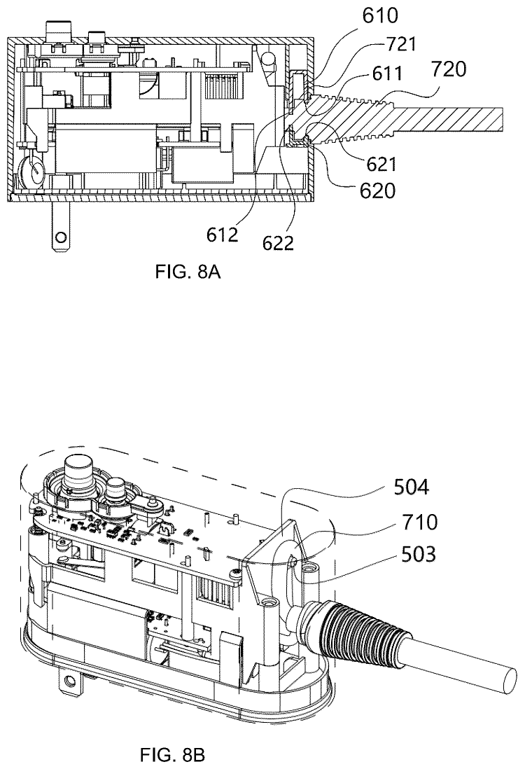

In this embodiment, the leakage protection device may further include a wire crimping (wire pressing) assembly 600, which is used to fix the power wires in the housing and is configured to move only in the plugging direction of the prongs to facilitate the assembly and fixation of the power cord. Specifically, the wire crimping assembly 600 is disposed in the housing and adjacent to the output through hole 101 of the housing. Referring to FIGS. 7 to 8B, the output power cord assembly 700 of the leakage protection device may also be provided with a power cord bending buffer device 720, and the power cord bending buffer device 720 is provided with a snap-fitting convex edge 721. The snap-fitting convex edge 721 can pass through the output through hole 101 of the housing and be matched and fixed with the wire crimping assembly 600.

In some embodiments, the wire crimping assembly 600 may include a first crimping block 610 and a second crimping block 620 disposed opposite to each other along the plugging direction of the prongs. The first crimping block 610 is provided with one or more first notches, and two first notches 611 and 612 are exemplarily shown in FIG. 8A. The second crimping block 620 is provided with one or more second notches, and two second notches 621 and 622 are exemplarily shown in the figure, so that the snap-fitting convex edge 721 is fixed between the two first notches 611 and 612 and between the two second notches 621 and 622. The first crimping block 610 and the second crimping block 620 may be fixed to each other via a crimping screw 630. A screw hole 623 on the second crimping block 620 is exemplarily shown in FIG. 7.

Advantageously, the first notches and/or the second notches are provided with inclined surfaces. For example, in the figure, the corresponding first notch 611 and second notch 621 are respectively provided with inclined surfaces. When the two crimping blocks are fastened by the crimping (wire pressing) screw 630, the inclined surfaces can be engaged with the snap-fitting convex edge 721 of the power cord bending buffer device 720, and the power cord bending buffer device 720 is made to fit with the edge of the output through hole 101 of the upper cover 100, further accomplishing the stable engagement of the wire crimping assembly with the power cord. In addition, the combination of the two notches can be engaged with the outer layer of the output power cord and compress and deform the outer layer of the power cord, so that it is fastened to the wire crimping assembly and the housing.

In some embodiments, a wire management block 503 may also be provided on the support frame 500 for bending the power cord. Also referring to FIGS. 7 to 8B, the wire management block 503 is disposed close to the output power cord assembly 700, and a wire baffle 504 is also optionally provided, where the wire management block 503 is disposed on the wire baffle 504. In this way, the wire baffle 504 separates the internal space of the housing to form a relatively independent wire storage space, which is beneficial to the positioning and protection of the power cord. When the output power cord assembly 700 is assembled and the core assembly 800 is being installed in the upper cover 100, the output power cord inside the housing can be arranged into a U-shaped feature 710 by the wire management block 503, which can be slid into and fixed in the wire storage space together with the core assembly 800.

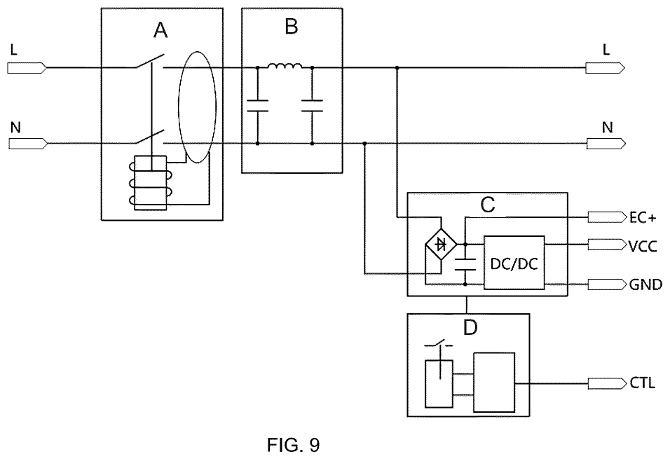

The working principle of the leakage protection device according to embodiments of the present invention is described below with reference to FIG. 9.

In FIG. 9, the leakage protection assembly and the additional functional assembly are schematically illustrated in a modular manner by region, including a leakage protection module A, an electromagnetic compatibility module B, a power conversion module C and a switch control module D. Under normal working conditions, when a leakage current is present at the output side (hot wire L, neutral wire N), the tripping coil assembly of the leakage protection module A receives a large current to generate a magnetic field, driving the tripping coil assembly to move, and disconnects the electrical connection between the input and output terminals to achieve leakage protection.

For additional functions, the electromagnetic compatibility module B can reduce the electromagnetic interference (EMI) in the circuit and improve the electromagnetic compatibility (EMC) of the circuit by using components such as capacitors and inductors. The power conversion module C can convert the external AC or DC current (such as EC+) at the input side into a DC output (such as VCC) that has been stabilized or converted by using components such as rectifiers and voltage regulators, thereby improving the stability of the DC output voltage. As a result, while ensuring the safety of the circuit, the EMC conduction interference signal is reduced, thereby reducing the interference to the transformer circuit, ensuring that the leakage protection device is less disturbed during operation, making the output DC voltage value more accurate and the error smaller, thereby achieving a better leakage protection effect. The switch control module D can be used to control the switch state of the circuit, allowing the on and off of the circuit to be controlled by receiving an external control signal (such as CTL).

By the above-described layout optimization design, the leakage protection device according to embodiments in the present invention can provide additional functions such as power conversion, electromagnetic compatibility, and switch control on the basis of the leakage protection function within a limited space in the housing, which increases integration of electrical appliances and provides users with a richer leakage protection device integration solution.

It should be understood that the embodiments shown in the drawings only illustrate the preferred shapes, sizes and spatial arrangements of the various components of the leakage current protection device. These illustrations do not limit the scope of the invention; other shapes, sizes and spatial arrangements may be used without departing from the spirit of the invention.

It will be apparent to those skilled in the art that various modification and variations can be made in the embodiments of the present invention without departing from the spirit or scope of the invention. Thus, it is intended that the present invention cover modifications and variations that come within the scope of the appended claims and their equivalents.

1. A leakage protection device with additional functions, comprising:
a housing;
an input terminal for coupling to a power supply;
an output terminal for coupling to an electrical load; and
a core assembly disposed in the housing, including:
a leakage protection assembly, including at least a leakage protection circuit board, configured to detect a leakage current signal at the output terminal;
an additional function assembly, coupled to the leakage protection assembly and including at least an additional function circuit board, configured to perform at least one load-end function,
wherein the leakage protection circuit board and the additional function circuit board are stacked in parallel with each other, and the leakage protection circuit board is located farther away from the input terminal than the additional function circuit board is.

2. The leakage protection device of claim 1, wherein the leakage protection assembly includes at least a detection assembly and a disconnection assembly, wherein the detection assembly is configured to detect a leakage current signal at the output end, and the disconnection assembly is configured to disconnect an electrical connection between the input terminal and the output terminal in response to the leakage current signal.

3. The leakage protection device of claim 2, wherein the detection assembly includes a detection magnetic ring, which has an inner hole and is coupled to the leakage protection circuit board, configured to detect the leakage current signal of power supply lines passing through the inner hole and to transmit the signal to the leakage protection circuit board.

4. The leakage protection device of claim 3, wherein the disconnection assembly includes an input stationary contact assembly coupled to the input terminal and an output moving contact assembly passing through the inner hole of the detection magnetic ring and coupled to the output terminal, wherein the disconnection assembly is configured to disconnect an electrical connection between the input stationary contact assembly and the output moving contact assembly in response to the leakage current signal.

5. The leakage protection device of claim 4, wherein the leakage protection assembly includes an operating assembly mechanically linked with the disconnection assembly, wherein the operating assembly includes a reset assembly and a trip assembly configured to switch the input stationary contact assembly and the output moving contact assembly between a connected state and a disconnected state.

6. The leakage protection device of claim 5, wherein the operating assembly further includes a test assembly, coupled to the leakage protection circuit board and configured to generate a simulated leakage signal.

7. The leakage protection device of claim 1, further comprising a heat sink, disposed near components on the leakage protection circuit board and/or the additional function circuit board that are heat-generating, configured to dissipate heat for the heat-generating components.

8. The leakage protection device of claim 7, further comprising a heat conductor disposed on the heat sink at a position corresponding to the heat-generating components, wherein the heat conductor is in contact with the heat-generating components and the heat sink respectively, and configured to transfer heat between the heat-generating components and the heat sink.

9. The leakage protection device of claim 7, further comprising an insulating member, disposed between the heat sink and the leakage protection circuit board and/or the additional function circuit board.

10. The leakage protection device of claim 1, further comprising a status indicator formed of a light-transmitting material and disposed between the leakage protection circuit board and the housing.

11. The leakage protection device of claim 1, wherein the input terminal includes at least two prongs extending out of the housing, and the leakage protection circuit board and the additional function circuit board are disposed perpendicular to a plugging direction of the prongs, and wherein the prongs are electrically coupled to the leakage protection circuit board or the additional function circuit board via prong wires.

12. The leakage protection device of claim 11, wherein the housing includes at least an upper cover and a bottom cover, wherein the upper cover includes an output terminal through hole configured to accommodate a power cord, and the bottom cover includes input terminal through holes configured for the prongs to pass through.

13. The leakage protection device of claim 12, wherein the housing further includes a middle cover disposed between the upper cover and the bottom cover, configured to fix the prongs.

14. The leakage protection device of claim 13, wherein the middle cover has screw holes configured to accommodate screws for fixing the middle cover to the upper cover or the bottom cover.

15. The leakage protection device of claim 13, wherein the bottom cover completely encloses the middle cover in the housing.

16. The leakage protection device of claim 1, further comprising a wire crimping assembly, configured to fix the power cord in the housing, wherein the wire crimping assembly is moveable only in a plugging direction of the prongs.

17. The leakage protection device of claim 16, further comprising a power cord bending buffer device, having a snap-fitting convex edge, wherein the snap-fitting convex edge passes through the output through hole of the housing and is matched and fixed with the wire crimping assembly.

18. The leakage protection device of claim 17, wherein the wire crimping assembly includes a first crimping block and a second crimping block disposed opposite to each other along the plugging direction of the prongs, wherein the first crimping block has a first notch, the second crimping block has with a second notch, wherein the first notch and/or the second notch has an inclined surface, wherein the inclined surface is engaged with the snap-fitting convex edge of the power cord bending buffer device.

19. The leakage protection device of claim 12, further comprising a support frame disposed between the leakage protection assembly and the additional function assembly, wherein the leakage protection circuit board and the additional function circuit board are electrically connected with each other via conductive columns passing through the support frame.

20. The leakage protection device of claim 12, wherein the support frame further includes a wire management block configured to bend the power cord.

21. The leakage protection device of claim 1, wherein the load-end function includes at least a power conversion function and/or an electromagnetic compatibility filtering function and/or a switch control function.
